(19) United States
(12) Patent Application Publication
(10) Pub. No.: US 2014/0273374 A1
(43) Pub. Date: Sep. 18, 2014

(54) Vertical Doping and Capacitive Balancing for Power Semiconductor Devices

(71) Applicants: Joseph Yedinak, Mountain Top, PA (US); Richard Stokes, Shavertown, PA (US); Sukhendu Deb Roy, Pune (IN); Steven Sapp, Felton, CA (US)

(72) Inventors: Joseph Yedinak, Mountain Top, PA (US); Richard Stokes, Shavertown, PA (US); Sukhendu Deb Roy, Pune (IN); Steven Sapp, Felton, CA (US)

(21) Appl. No.: 13/842,694

(22) Filed: Mar. 15, 2013

(51) Int. Cl. H01L 29/66

(52) U.S. Cl. CPC H01L 29/66666
USPC 438/272

(57) ABSTRACT

Vertical doping in power semiconductor devices and methods for making such dopant profiles are described. The methods include providing a semiconductor substrate, providing an epitaxial layer on the substrate, the epitaxial layer comprising a bottom portion containing a first conductivity type dopant in a substantially constant, first concentration throughout the bottom portion; and an upper portion containing a first conductivity type dopant having a second concentration lower than the first concentration; providing a trench in the epitaxial layer; forming a transistor structure in the trench; and forming a well region in the upper part of the epitaxial layer adjacent the trench, the well region containing a second conductivity type dopant that is opposite the first conductivity type. Other embodiments are described.

### FIELD

This application relates generally to power semiconductor devices and methods for making such devices. More specifically, this application describes vertical doping and capacitive balancing in power semiconductor devices and methods for making such dopant profiles.

### BACKGROUND

Semiconductor devices containing integrated circuits (ICs) or discrete devices are used in a wide variety of electronic apparatus. The IC devices (or chips, or discrete devices) comprise a miniaturized electronic circuit that has been manufactured in the surface of a substrate of semiconductor material. The circuits are composed of many overlapping layers, including layers containing dopants that can be diffused into the substrate (called diffusion layers) or ions that are implanted (implant layers) into the substrate. Other layers are conductors (polysilicon or metal layers) or connections between the conducting layers (via or contact layers). IC devices or discrete devices can be fabricated in a layer-by-layer process that uses a combination of many steps, including growing layers, imaging, deposition, etching, doping and cleaning. Silicon wafers are typically used as the substrate and photolithography is used to mark different areas of the substrate to be doped or to deposit and define polysilicon, insulators, or metal layers.

Power semiconductor devices are often used as switches or rectifiers in electronic circuits. When connected to a circuit board, they can be used in a wide variety of apparatus including automotive electronics, disk drives and power supplies. Some power semiconductor devices can be formed in a trench that has been created in a substrate. One feature making the trench configuration attractive is that the current flows vertically through the channel of the devices located adjacent and between two trenches. This permits a higher cell and/or current channel densities than other semiconductor devices where the current flows horizontally through the channel and then vertically through the drain. Greater cell and/or current channel densities generally mean more devices and/or current channels can be manufactured per unit area of the substrate, thereby increasing the current density of the power semiconductor device.

### SUMMARY

This application describes vertical doping and capacitive balancing in power semiconductor devices and methods for making such dopant profiles. The methods include providing a semiconductor substrate; providing an epitaxial layer on the substrate, the epitaxial layer comprising a bottom portion containing a first conductivity type dopant in a substantially constant, first concentration throughout the bottom portion; and an upper portion containing a first conductivity type dopant having a second concentration lower than the first concentration; providing a trench in the epitaxial layer; forming a transistor structure using trenches that extends through the upper part of the epi layer and into or through the bottom epi layer; and forming a well region with a junction depth less than the upper epitaxial layer or a junction depth ending in a doping concentration level that is less than the bottom epitaxial layer. Adjacent the trench, the well region can contain a second conductivity type dopant that is opposite the first conductivity type. Such methods reduce the surface electric field so that higher mesa doping in the lower epi layer or layers can be used to reduce the specific resistance and improve the body diode recovery characteristics in the power semiconductor devices while being able to maintain the rated source-to-drain breakdown voltage (BVdss) and maintaining the avalanche impact ionization below the p-well junction.

### BRIEF DESCRIPTION OF THE DRAWINGS

The following description can be better understood in light of the Figures, in which:

FIG. 1 shows some embodiments of methods for making a semiconductor structure containing a substrate and an epitaxial (or “epi”) layer with a mask on the upper surface of the epitaxial layer;

FIG. 2 depicts some embodiments of methods for making a semiconductor structure containing two trench structures with a mesa structure between the trenches;

FIG. 3 shows some embodiments of methods for making a semiconductor structure with an oxide layer and a conductive layer formed in the trenches;

FIG. 4 shows some embodiments of methods for making a semiconductor structure where a conductive layer has been etched to form a shield electrode in the trenches;

FIG. 5 depicts some embodiments of methods for making a semiconductor structure were the trench is filled with an insulating layer above the shield electrode;

FIG. 6 depicts some embodiments of methods for making a semiconductor structure with an insulating layer recessed in the trench above the shield electrode in the trenches to form an IPD (inter poly dielectric) layer;

FIG. 7 depicts some embodiments of methods for making a semiconductor structure where an insulating layer is grown on the upper trench sidewall to form a gate oxide and then filled with a conductive layer and etched below the mesa surface to form a gate electrode;

FIG. 8 shows some embodiments of methods for making a semiconductor structure with a shield gate MOSFET structure formed in the trench and p-regions (p-well) formed in the epitaxial layer;

FIG. 9 shows some embodiments of methods for making a semiconductor structure with an inter level dielectric (ILD) layer formed over the gate electrode;

FIG. 10 shows some embodiments of methods for making a semiconductor structure with a shield gate MOSFET structure formed in the trench and source regions formed in the p-regions (p-well);

FIG. 11 shows some embodiments of methods for making a semiconductor structure with a shield gate MOSFET structure formed in the trench and a dimple is etched in the mesa to form the source and body contacts;

FIG. 12 shows some embodiments of methods for making a semiconductor structure with a shield gate MOSFET structure formed in the trench and a conductive layer deposited to make an ohmic contact;

FIG. 13 illustrates some embodiments of the dopant profile of the epitaxial layer in the semiconductor devices;

FIG. 14 illustrates some embodiments of the electric field profile and post processing dopant profile of the semiconductor devices at breakdown;

FIG. 15 illustrates a comparison of output capacitance (Coss) comparison curves for some conventional semiconductor devices and for some embodiments of the semiconductor devices described herein;

FIG. 16 illustrates a diode recovery waveform of some conventional semiconductor devices (on the left) compared to some embodiments of the semiconductor devices described herein (on the right); and

FIG. 17 depicts a conventional minority carrier concentration profiles through the mesa center during body diode recovery of some conventional semiconductor devices (on the left) compared to some embodiments of the semiconductor devices (on the right) described herein.

The Figures illustrate specific aspects of the power semiconductor devices and methods for making such devices. Together with the following description, the Figures demonstrate and explain the principles of the methods and structures produced through these methods. In the drawings, the thickness of layers and regions are exaggerated for clarity. The same reference numerals in different drawings represent the same element, and thus their descriptions will not be repeated. As the terms on, attached to, or coupled to are used herein, one object (e.g., a material, a layer, a substrate, etc.) can be on, attached to, or coupled to another object regardless of whether the one object is directly on, attached, or coupled to the other object or there are one or more intervening objects between the one object and the other object. Also, directions (e.g., above, below, top, bottom, side, up, down, under, over, upper, lower, horizontal, vertical, “x,” “y,” “z,” etc.), if provided, are relative and provided solely by way of example and for ease of illustration and discussion and not by way of limitation. In addition, where reference is made to a list of elements (e.g., elements a, b, c), such reference is intended to include any one of the listed elements by itself, any combination of less than all of the listed elements, and/or a combination of all of the listed elements.

### DETAILED DESCRIPTION

The following description supplies specific details in order to provide a thorough understanding. Nevertheless, the skilled artisan would understand that the semiconductor devices and associated methods of making and using the devices can be implemented and used without employing these specific details. Indeed, the semiconductor devices and associated methods can be placed into practice by modifying the illustrated devices and methods and can be used in conjunction with any other apparatus and techniques conventionally used in the industry. For example, while description refers to trench MOSFET devices, it could be modified for other power semiconductor devices formed with trenches, such as Static Induction Transistor (SIT) devices, Static Induction Thyristor (SITh) devices, IGBT devices, BJT devices, JFET devices, Mos Controlled thyristor (MCT) devices, and Trench Barrier Schottky (TMBS).

Some embodiments of the power semiconductor devices and methods for making such devices are shown in FIGS. 1-14. The methods begin in some embodiments, as depicted in FIG. 1, when a semiconductor substrate 105 is first provided. Any substrate known in the art can be used in the invention. Suitable substrates include silicon wafers, epitaxial Si layers, bonded wafers such as used in silicon-on-insulator (SOI) technologies, and/or amorphous silicon layers, all of which may be doped or undoped. Also, any other semiconducting material used for electronic devices can be used, including Ge, SiGe, SiC, GaN, GaAs, InₓGa_{y}As_{z}, AlₓGa_{y}As_{z}, and/or any pure or compound semiconductors, such as III-V or II-VIs and their variants. In some embodiments, the substrate 105 can be heavily doped with any n-type dopant.

In some embodiments, the substrate 105 contains one or more epitaxial (“epi”) Si layers (individually or collectively depicted as epitaxial layer 110) located on an upper surface thereof. The epitaxial layer(s) 110 can be provided using any process, including any epitaxial deposition process. In some embodiments, the epitaxial layer 110 can be configured so that it comprises a lower dopant concentration the upper portion of the epitaxial layer and a higher dopant concentration in the bottom portion of the epitaxial layer.

Some conventional power trench MOSFET devices contain a dopant profile that is consistent throughout the epitaxial layer so that the dopant concentration in the bottom portion of the epitaxial layer is the same as the concentration of the upper portion of the epitaxial layer. This conventional dopant profile is depicted by the red line X and blue line Y in FIG. 13, which shows the dopant concentration along the length of the epitaxial layer 110 with the upper surface of the epitaxial layer 110 shown on the left and the substrate on the right. As seen in FIG. 13, the dopant concentration in these conventional semiconductor devices is generally higher in the substrate region (section C) and then decreases to a relatively constant level in the epitaxial layer 110 (sections A and B).

FIG. 13 also illustrates those embodiments where the epitaxial layer 110 comprises a lightly doped upper potion (near the upper surface of the epitaxial layer 110). These embodiments are shown by the black line C in FIG. 13. Like the conventional devices, they contain a dopant concentration that is generally higher in the substrate 105 and then decreases to a constant level in bottom portion (B) of the epitaxial layer 110. But unlike these conventional devices, the dopant concentration is reduced in the upper portion (A) near the upper surface of the epitaxial layer 110.

In other embodiments, the semiconductor devices may include graded epitaxial layers for either the bottom portion (B) and upper epitaxial portion (A) that have higher doping near the substrate and lighter doping towards the surface. To achieve higher breakdown voltage devices or the desired electrical effect, multiple intermediate epitaxial layers maybe inserted between the bottom portion (B) and the top portion (A) that have a doping that is lower than the bottom portion (B) and heavier than the top portion (A). Each inserted epitaxial layer may progressively be lighter doping as it is grown towards the upper surface and may contain a graded doping profile that becomes lower towards the upper surface.

In some configurations of the semiconductor devices described herein, the dopant concentration in the substrate 105 can range from about 1e18 atoms/cm³ to about 1e21 atoms/cm³ and the dopant concentration in the bottom portion of the epitaxial layer can range from about 5e15 atoms/cm³ to about 3e17 atoms/cm³. In other configurations, the dopant concentration in the substrate 105 can be about 5e19 atoms/cm³ and the dopant concentration in the bottom portion of the epitaxial layer can be about 8e16 atoms/cm³.

In the embodiments illustrated in FIG. 13, the dopant concentration in the upper portion (A) can remain substantially constant. In these embodiments, the dopant concentration near the upper surface can range from about 1e13 atoms/cm³ to about 1e16 atoms/cm³. In other embodiments, though, this lower dopant concentration can range from about 1e14 atoms/cm³ to about 1e15a/cm3. In yet other embodiments, though, this lower dopant concentration can be about 1×10¹⁵ atoms/cm³ in the upper portion of the epitaxial layer 110. In other configurations, though, the dopant concentration in the upper portion (A) need not remain substantially constant.

The thickness of this region of lower dopant concentration (i.e., the upper portion) depends on the well junction depth, the thermal exposure during the processing that can redistribute the doping, the reduction of the layer thickness due to oxidations and etches that consume or remove silicon from the surface, as well as the characteristics of the device that will be formed in the epitaxial layer (i.e., the shield gate trench MOSFET). In some embodiments, the thickness of this lower dopant region can range from about 1 micron to about 10 microns. In other embodiments, the thickness of this lower dopant region can range from about 3 microns to about 6 microns. In yet other embodiments, the thickness of this lower dopant region can be about 3 microns. This thickness compares to the thickness of the bottom portion (B) of the epitaxial layer 110 (where the dopant concentration is relatively constant) which can range from about 5 microns to about 50 microns and, in some embodiments can be about 9 microns.

The dopant concentration (of the black line Z) illustrated in FIG. 13 can be obtained using any process that will provide the doping profile illustrated and described herein. In some embodiments, this doping profile can be obtained by growing the bottom portion of the epitaxial layer 110 on the substrate 105 using first epitaxial process that uses a higher dopant concentration in the atmosphere. Then, the upper portion of the epitaxial layer 110 can be grown over the bottom portion of layer using a second epitaxial process with a lower dopant concentration. Alternatively, all of the epi layers can be grown using an in situ process.

Next, as shown in FIG. 2, a first trench structure 120 (or trench) can be formed in the epitaxial layer 110. The bottom of the first trench 120 can reach anywhere in epitaxial layer 110 or substrate 105. The first trench structure 120 can be formed by any process yielding the desired structure. In some embodiments, a mask 115 can be formed on the upper surface of the epitaxial layer 110. The mask 115 can be formed by first depositing a layer of the desired mask material and then patterning it using a photolithography and an etch process so the desired pattern for the mask 115 is formed. After the etching process used to create the trench 120 is complete, a mesa structure (or mesa) 112 has been formed between adjacent trenches 120, as shown in FIG. 2.

The epitaxial layer 110 can then be etched by any process until the first trench 120 has reached the desired depth and width in the epitaxial layer 110 (or substrate 105). The depth and width of the trench 120, as well as the aspect ratio of the width to the depth, can be controlled so that so a later deposited oxide layer properly lines the trench sidewalls and bottom or fills in the trench and avoids the formation of voids. In some embodiments, the depth of the first trench structure 120 can range from about 0.1 to about 100 μm and the width can range from about 0.1 to about 50 μm. With such depths and widths, the aspect ratio of the trench can range from about 1:1 to about 1:50.

In some embodiments, the sidewalls of the trenches 120 are not perpendicular to the upper surface of the epitaxial layer 110. Instead, the angles of the trench sidewall can range from about 90 degrees (a vertical sidewall) to about 60 degrees relative to the upper surface of the epitaxial layer 110. The trench angle can be controlled so a later deposited oxide layer or any other material properly lines the trench sidewalls and/or fills in the trench and avoids the formation of voids. The mask 115 can next be removed using any process.

In some embodiments, as shown in FIG. 3, an oxide layer 130 (or other insulating or semi-insulating material) can then be formed on the trench sidewalls 120. The oxide layer 130 can be formed by any process, including depositing an oxide material, growing an oxide layer or combination thereof on the trench 120 sidewalls. The thickness of the oxide layer 130 can be adjusted to any thickness needed on the trench 120 sidewalls required to support a desired device breakdown voltage or obtain a desired electric field profile. The deposition of the oxide material can be carried out using any known deposition process, including any chemical vapor deposition (CVD) processes, such as SACVD which can produce a highly conformal step coverage within the trench. If needed, a reflow process can be used to reflow the oxide material, which will help reduce voids or defects within the oxide layer 130 and densify the oxide material.

Then, as shown in FIG. 3, a conductive layer 140 can be deposited over the oxide layer 130 in the trenches 120. The conductive layer 140 can comprise any conductive and/or semiconductive material known in the art including any metal, silicide, semiconducting material, doped polysilicon, or combinations thereof. In some embodiments, the conductive layer comprises doped or undoped polysilicon. This conductive layer 140 can be deposited by any known deposition process, including chemical vapor deposition processes (CVD, PECVD, LPCVD, etc.) or sputtering processes using the desired metal as the sputtering target.

The conductive layer 140 can be deposited so that it fills and overflows over the trenches 120 and the insulating layer 130, as shown in FIG. 3. Then, as shown in FIG. 4, a shield electrode 150 (or shield 150) can be formed from the conductive layer 140 using any process. In some embodiments, the shield 150 can be formed by removing the upper portion of the conductive layer 140 using any process, including any etchback process. The result of the removal process leaves a conductive layer (the shield 150) overlying the oxide layer 130 on the bottom of the trench 120 and between the sidewall oxide layers 130, as shown in FIG. 4.

An insulating layer 145 can then be formed in the trenches 120. The insulating layer 145 can be deposited so that it fills and overflows over the trenches 120, as shown in FIG. 5. The insulating layer 145 can be formed by any process. In some embodiments, the insulating layer can be formed by depositing an insulating material (such as an oxide) until it overflows the trenches 120. The deposition of the oxide material can be carried out using any known deposition process, including any chemical vapor deposition (CVD) processes, such as SACVD which can produce a highly conformal step coverage within the trench. The insulating layer 145 is then etched back to remove the excess material above shield electrode 150 in the trenches 120 to form an interpoly dielectric (IPD) layer 155, as shown in FIG. 6.

After the etch back process, an insulating layer (or gate oxide layer 165) can be formed on the sidewalls of the trench 120 above the shield electrode 150, as shown in FIG. 7. In these embodiments, a high quality material for the gate oxide layer can be formed by oxidizing the epitaxial layer 110 in an oxide-containing atmosphere until the desired thickness of the high-quality oxide layer has been grown. The high quality material in the gate oxide layer 165 can be used to improve the oxide integrity and thereby making the insulating layer a better insulator.

Next, a gate electrode (or gate) 160 of the MOSFET device can be formed in the trench 120 as shown in FIG. 7. The gate 160 can comprise any conductive and/or semiconductive material including any metal, silicide, semiconducting material, doped polysilicon, or combinations thereof. The conductive material for the gate 160 can be deposited by any known deposition process, including chemical vapor deposition processes (CVD, PECVD, LPCVD, etc.) or sputtering processes using the desired metal as the sputtering target. The conductive material can be deposited so that it fills and overflows over the trenches 120 after which the gate electrode 160 can be formed by removing the upper portion of the conductive layer using any process, including any etchback process. The result of the removal process leaves a conductive layer (the gate 160, typically made of polysilicon) overlying the IPD layer 155, as shown in FIG. 7.

In some embodiments, as shown in FIG. 8, the mesa region 112 can be doped with a p-type dopant so that a well region is formed in the epitaxial layer 110 between two trenches and along trench sidewalls 120. The mesa doping process can be performed using any doping process which implants the p-type dopants to the desired depth. After the doping process, the p-type dopants can be further diffused by any known diffusion or drive-in process to the desired depth of the junction with the epitaxial layer 110, known as the p-well junction (Pwell Xj) 172.

An insulating layer (such as BPSG) can then be formed in the top of the trenches 120 above the gate electrode 160. The insulating layer can be formed by any process, including by depositing an oxide material until it overflows the trenches 120. The thickness of the insulating layer can be adjusted to any thickness needed to fill the top of the trenches 120. The deposition of the insulating material can be carried out using any known deposition process, including any chemical vapor deposition (CVD) processes, such as SACVD which can produce a highly conformal step coverage within the trench. After the insulating layer has been deposited, an etchback process can be used to remove the excess material above the trenches 120, thereby forming an interlevel dielectric (ILD) layer 177 in the upper part of the trench 120.

Then, a n-type source region can be formed in an upper portion of the p-well region until it reaches the junction (Xj) depth 175, as shown in FIG. 10. The source region 175 can be formed using the n-type dopants implanted and diffused from the surface of epitaxial region 110. Then, a dimple 180 can be etched in the surface of epitaxial region 110 to form the source and body contacts, as shown in FIG. 11. A conductive material 185 can then be deposited and annealed to make ohmic contacts to the source and body regions, as shown in FIG. 12.

FIG. 13 illustrates some embodiments of the shield gate semiconductor devices described herein. These semiconductor structures formed herein are illustrated in the top part of FIG. 13 with the upper surface of the epitaxial layer 110 (containing the p-well region) on the left side of the upper part of FIG. 13 and the lower part of the epitaxial layer 110 on the right side. The other parts of the shielded gate trench MOSFET structure are also illustrated in the top part of FIG. 13.

These shield gate trench MOSFET devices can be operated until breakdown condition is achieved. The final dopant profile of the device after processing is measured along the cross-section of the device shown by the dashed line (which runs through the center of the mesa 112 of the semiconductor device in the top of FIG. 14) and is displayed in the bottom graph of FIG. 14. At that breakdown point, the electric profile of the device is also measured along the same cross-section and then displayed in the middle portion of FIG. 14.

In the middle portion of FIG. 14, the graph shows the electric field profile (shown by lines C and D) at the breakdown point of the devices described herein as compared to the electric field profile at breakdown of conventional devices (shown by lines A and B). As shown in FIG. 14, a minimum shield oxide thickness 130 is required for the desired break down voltage. The shield oxide thickness, mesa doping profile and mesa charge can determine the electric profile in the mesa 12. The A lines in FIG. 14 represent a doping profile and electric field profile of a some conventional devices having a single epitaxial layer represented by initial doping profile X in FIG. 13 with the same doping concentration as the bottom epitaxial layer doping profile Z in FIG. 13 of the devices described herein.

As seen in the Table at the top of FIG. 14, for some conventional semiconductor device containing a single epitaxial layer, the mesa charge is too high and results in a breakdown voltage of only 38 volts because the critical electric field is reached in the silicon close to the top of the trench near p-well junction. The B lines in FIG. 14 represent a doping profile and electric field profile of some conventional devices having a single epitaxial layer represented by doping profile Y in FIG. 13. For these conventional devices containing a single epitaxial layer, the mesa charge is optimized to achieve the highest breakdown with same shield oxide thickness as the semiconductor devices described herein. The specific on-resistance (RSP) is higher and an electric field profile that is not efficient resulting in a breakdown voltage of only 101V.

Compared to these drawbacks, the lightly doped region near the surface of the epitaxial layer 110 (as described herein) provides two benefits. First, as shown by line C, the lightly doped region contributes to reducing and suppressing the increase of the electric field near the p-well junction to achieve a breakdown voltage, thereby allowing an increase in epitaxial doping in the bottom epitaxial layer to reduce the on-resistance (Rdson). And second, as shown by line D, the lightly doped region near the epitaxial surface contributes to reducing and suppressing the increase of the electric field near the p-well junction and along the entire mesa depth between the trenches to achieve a breakdown voltage, thereby allowing an increase in epitaxial doping in the bottom epitaxial layer to reduce the on-resistances (Rdson).

As shown in the lower part of FIG. 14, the graph shows the final dopant profile (shown by lines C and D) after processing of the devices described herein when compared to the dopant profile after processing of conventional devices (shown by lines A and B). This final dopant profile increases the doping in the bottom epitaxial layer to reduce on-resistance while preventing the silicon from reaching critical field near the P-well junction 172, resulting in reduced breakdown voltage.

These methods of manufacturing and the power semiconductor devices formed have several useful features. First, they allow for higher mesa drift doping between the trenches 120 to achieve lower on-resistance performance while maintaining a high breakdown voltage. Second, the optimization of the shield oxide thickness 130 with the drift doping profile and mesa width between the trenches 120 can achieve a balanced condition that does not result in the mesa regions between adjacent trenches 120 to be fully depleted when a drain to source voltage (Vds) is applied that is equal to or lower than the rated device voltage.

Both the drift doping profile and the optimization of the balance condition result in a performance improvement during body diode recovery for peak reverse recovery current (Irrm), di/dt of the recovery current during the time it takes the drain current to go from Irrm to 25% of Irrm (tb), drain voltage overshoot, and recovery losses. One factor contributing to the performance improvement and minimizing the time from the point the current crosses zero and decreases to Irrm (ta), as shown in FIG. 16, is achieving a level of hole carrier injection below—or as close as possible to—the background concentration and low minority carrier lifetime in the mesa region. Thus, when the current crosses zero, the semiconductor device is the ta phase for a shorter time and Irrm and Qrr can be reduced. A second contributing factor in charge-balanced semiconductor devices is that when the mesa becomes fully depleted, the depletion edge cannot expand anymore since it reaches the bottom of the trench or drift region below the trench. At that point, an abrupt change in the dv/dt can occur that can drive the device into avalanche. But this situation can be avoided if the applied voltage is lower than the voltage at which the mesa is full depleted, as noted in the capacitance curve for the conventional devices in FIG. 15. In the semiconductor devices described herein, though, the mesa does not fully deplete up to the 100 volt rating of the device.

The body diode recovery for some conventional semiconductor devices (on the left) compared to the semiconductor devices described herein (on the right) is shown in FIG. 16. These conventional devices have a single epi doping profile of 1.26e16 atoms/cm³, which is inferior to the body diode recovery of the semiconductor devices described herein. The conventional body diode recovery (in the left of FIG. 16) has higher peak reverse current (Irrm) labeled as IdsMOSD in FIG. 16, reverse recovery charge (Qrr), snappy recovery (low ratio of tb/ta), and device is driven into avalanche shown by VsdMOSD in FIG. 16 posing a risk for device failure. The poor body diode recovery for these conventional devices results from a minority carrier hole concentration level during forward body diode conduction that is higher than the drift doping level labeled as Vsd in FIG. 17, as shown by the profile labeled Vsd.

At the same time, a slower recombination of minority carriers below background doping results from a higher minority carrier concentration dependent lifetime of the lower drift doping that increases the time to onset of reverse blocking. This situation occurs when the minority carrier concentration level falls below the mesa drift doping near the p-well junction, as shown in FIG. 17 in the carrier profile labeled “start reverse blocking.” Thus, to and Irrm become too large in these conventional devices and the recovery current tb does not transition to mostly capacitive shield charging current labeled IsMOSD in FIG. 16. The lower output capacitance (Coss) at a Vdd of 50V, as shown in FIG. 15, and the depletion of the mesa region occurring at a voltage less than the applied Vdd causes a secondary fast drain dv/dt, thereby driving these conventional devices into avalanche during tb, as shown in FIG. 16.

The improved body diode recovery performance of the devices described herein is due, in part, to an injected hole carrier concentration that is below the background labeled as Vsd in FIG. 17, a slower rate of voltage rise (dv/dt), optimization of shield capacitance and balance condition to prevent full mesa depletion at voltages less than the applied voltage, and lower minority carrier lifetime due to enabling the use of higher concentration doping in the lower drift region or regions. The body diode recovery shown on the right in FIG. 16 with a starting epitaxial doping profile Z in FIG. 13 and finished processed doping profile D in FIG. 14 is superior to the body diode recovery of the conventional device in FIG. 16. The body diode recovery shown on the right in FIG. 16 has lower Irrm labeled as IdsMOSD in FIG. 16, lower Qrr, softer recovery (high ratio of tb/ta), and lower drain overshoot voltage labeled as VsdMOSD in FIG. 16. This improved body diode recovery results from a minority carrier hole concentration level during forward body diode conduction that is lower than the drift doping level, as shown in the FIG. 17 profile labeled Vsd. A faster recombination of minority carriers below the background doping resulting from a lower minority carrier concentration dependent lifetime of lower drift doping decreases the time to the onset of reverse blocking, as shown in the FIG. 17 carrier profile labeled “start reverse blocking.” Thus, to and Irrm become lower for the devices described herein. The recovery current during tb can transition to mostly capacitive shield charging current labeled IsMOSD in FIG. 16 and a higher Coss at Vdd of 50V, as shown in FIG. 15, and a mesa region that is not fully depleted at voltages less than the applied Vdd, thereby resulting in a slower dv/dt that can be controlled by the charging of the Coss and a low Vds overshoot during tb, as shown in FIG. 16.

It is understood that all material types provided herein are for illustrative purposes only. Accordingly, while specific dopants are names for the n-type and p-type dopants, any other known n-type and p-type dopants (or combination of such dopants) can be used in the semiconductor devices. As well, although the devices of the invention are described with reference to a particular type of conductivity (P or N), the devices can be configured with a combination of the same type of dopant or can be configured with the opposite type of conductivity (N or P, respectively) by appropriate modifications.

In some embodiments, the application relates to a shielded gate MOSFET device comprising a semiconductor substrate; an epitaxial layer on the substrate, the epitaxial layer containing a bottom portion containing a first conductivity type dopant in a substantially constant, first concentration throughout the bottom portion and an upper portion containing a first conductivity type dopant having a second concentration lower than the first concentration; a trench in the epitaxial layer; an insulating layer on the bottom and sidewalls of the trench; a conductive shield on the insulating layer; an interlevel dielectric layer on the conductive shield; a gate on the interlevel dielectric layer; an insulation cap on the gate; and a well region in the upper part of the epitaxial layer adjacent the trench, the well region containing a second conductivity type dopant that is opposite the first conductivity type.

In addition to any previously indicated modification, numerous other variations and alternative arrangements may be devised by those skilled in the art without departing from the spirit and scope of this description, and appended claims are intended to cover such modifications and arrangements. For example, the upper portion of the epitaxial layer can extend below the well region by about 0.5 microns, the upper portion of the epitaxial layer can extend below the well region by more than about 0.5 microns, the upper portion dopant concentration can decrease towards the surface, the bottom portion dopant concentration can decrease towards the surface, the bottom portion dopant concentration can be higher than the upper portion dopant concentration and both can have decreasing concentration towards the surface, the intermediate portions can be inserted between the lower portion and the upper portion and some (or all) can have successively increasing dopant levels toward the substrate, the second concentration in the upper portion of the epitaxial layer reduces and flattens the electric field near the junction with well region, a higher mesa drift doping can be created between the trenches and achieve a lower on-resistance performance while maintaining a high breakdown voltage, the mesa region is not full depleted at about 50% rated drain voltage, the mesa region is not full depleted at about 80% rated drain voltage, the mesa region is not full depleted at the rated drain voltage, and/or the minority carrier concentration level during body diode conduction is lower than the bottom portion dopant concentration.

Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A method for making semiconductor structure, comprising:
providing a semiconductor substrate;
providing an epitaxial layer on the substrate, the epitaxial layer comprising:
a bottom portion containing a first conductivity type dopant in a substantially constant, first concentration throughout the bottom portion; and
an upper portion containing a first conductivity type dopant having a second concentration lower than the first concentration;
providing a trench in the epitaxial layer;
forming a transistor structure in the trench; and
forming a well region in the upper part of the epitaxial layer adjacent the trench, the well region containing a second conductivity type dopant that is opposite the first conductivity type.

2. The method of claim 1, wherein the transistor structure comprises a shielded gate MOSFET device.

3. The method of claim 1, wherein the upper portion of the epitaxial layer extends to just below the well region.

4. The method of claim 1, wherein the first dopant concentration ranges from about 5×10¹⁵ atoms/cm³ to about 3×10¹⁷ atoms/cm³.

5. The method of claim 1, wherein the second dopant concentration ranges from about 1×10¹³ atoms/cm³ to about 1×10¹⁶ atoms/cm³.

6. The method of claim 1, wherein the second dopant concentration is about 1×10¹⁵ atoms/cm³.

7. The method of claim 2, wherein the second concentration in the upper portion of the epitaxial layer reduces and flattens the electric field near the junction with well region.

8. The method of claim 1, wherein the method creates a higher mesa drift doping between the trenches and achieves a lower on-resistance performance while maintaining a high breakdown voltage.

9. A method for making a power semiconductor device, comprising:
providing a semiconductor substrate;
providing an epitaxial layer on the substrate, the epitaxial layer comprising:
a bottom portion containing a first conductivity type dopant in a substantially constant, first concentration throughout the bottom portion; and
an upper portion containing a first conductivity type dopant having a second concentration lower than the first concentration;
providing a trench in the epitaxial layer;
forming a transistor structure in the trench; and
forming a well region in the upper part of the epitaxial layer adjacent the trench, the well region containing a second conductivity type dopant that is opposite the first conductivity type.

10. The method of claim 9, wherein the transistor structure comprises a shielded gate MOSFET device.

11. The method of claim 9, wherein the upper portion of the epitaxial layer extends to just below the well region.

12. The method of claim 9, wherein the first dopant concentration ranges from about 5×10¹⁵ atoms/cm³ to about 3×10¹⁷ atoms/cm³.

13. The method of claim 9, wherein the second dopant concentration ranges from about 1×10¹³ atoms/cm³ to about 1×10¹⁶ atoms/cm³.

14. The method of claim 9, wherein the second dopant concentration is about 1×10¹⁵ atoms/cm³.

15. The method of claim 10, wherein the second concentration in the upper portion of the epitaxial layer reduces and flattens the electric field near the junction with well region.

16. The method of claim 9, wherein the method creates a higher mesa drift doping between the trenches and achieves a lower on-resistance performance while maintaining a high breakdown voltage.

17. A method for making a shielded gate MOSFET device, comprising:
providing a semiconductor substrate;
providing an epitaxial layer on the substrate, the epitaxial layer comprising:
a bottom portion containing a first conductivity type dopant in a substantially constant, first concentration throughout the bottom portion; and
an upper portion containing a first conductivity type dopant having a second concentration lower than the first concentration;
providing a trench in the epitaxial layer;
forming an insulating layer on the bottom and sidewalls of the trench;
forming a conductive shield on the insulating layer;
forming an interlevel dielectric layer on the conductive shield;
forming a gate on the interlevel dielectric layer;
forming an insulation cap on the gate; and
forming a well region in the upper part of the epitaxial layer adjacent the trench, the well region containing a second conductivity type dopant that is opposite the first conductivity type.

18. The method of claim 17, wherein the first dopant concentration ranges from about 5×10¹⁵ atoms/cm³ to about 3×10¹⁷ atoms/cm³.

19. The method of claim 17, wherein the second dopant concentration ranges from about 1×10¹³ atoms/cm³ to about 1×10¹⁶ atoms/cm³.

20. The method of claim 17, wherein the second dopant concentration is about 1×10¹⁵ atoms/cm³.

21. The method of claim 1, wherein the trench extends below the upper portion of the epitaxial layer.

22. The method of claim 21, wherein the trench extends into the substrate.

23. The method of claim 1, wherein the doping concentration of the upper portion decreases towards the surface of the substrate.

24. The method of claim 1, wherein the doping concentration of the bottom portion decreases towards the surface of the substrate.

25. The method of claim 1, wherein the bottom portion dopant concentration is higher than the upper portion dopant concentration and both the upper and bottom portions have a decreasing dopant concentration towards the surface of the substrate.

26. The method of claim 1, further comprising an intermediate portion located between the lower portion and the upper portion and the intermediate portion has an increasing dopant concentration toward the surface of the substrate.

27. The method of claim 1, wherein the minority carrier lifetime is reduced by introducing traps in the mesa drift region between the trenches
